(19) United States
(12) Patent Application Publication
(10) Pub. No.: US 2026/0153588 A1
(43) Pub. Date: Jun. 4, 2026

(54) QUANTUM DIRECTION FINDER WITH 2D RYDBERG ATOMIC ARRAY

(71) Applicants: Shane Verploegh, Boulder, CO (US); Eric Magnuson Bottomley, Broomfield, CO (US); Seth Charles Caliga, Lafayette, CO (US); Haoquan Fan, Erie, CO (US)

(72) Inventors: Shane Verploegh, Boulder, CO (US); Eric Magnuson Bottomley, Broomfield, CO (US); Seth Charles Caliga, Lafayette, CO (US); Haoquan Fan, Erie, CO (US)

(21) Appl. No.: 18/948,827

(22) Filed: Nov. 15, 2024

Related U.S. Application Data
(60) Provisional application No. 63/599,958, filed on Nov. 16, 2023.

(51) Int. Cl. G01S 3/04; G01R 29/08

(52) U.S. Cl. CPC G01S 3/043; G01R 29/0885

(57) ABSTRACT

Examples relate to a quantum radio frequency (RF) electromagnetic (EM) signal direction finding system. The system includes an arrangement of quantum sensor elements configured to detect RF EM signals, with excitation componentry to optically excite the elements and photodetector circuitry to detect optical emission. A laser system and optical system provide excitation light, while an electronic control and processing circuit receives signals from the photodetector circuitry. The electronic control and processing circuit processes the signals to determine phase differences between elements and calculates an angle of arrival of incoming wireless RF signals.

### CROSS-REFERENCE TO RELATED APPLICATIONS

This application claims the benefit of priority to U.S. Provisional Application Ser. No. 63/599,958, filed Nov. 16, 2023, the content of which is incorporated herein by reference in its entirety

### BACKGROUND

Radio direction finding (RDF), and geolocation are used in diverse applications such as measurement and signals intelligence, navigation, and search and rescue. Antenna arrays can be configured to detect and process RF signals across different frequency bands. Phase interferometry methods analyze phase relationships between multiple antenna elements to calculate angles of arrival.

Improvements on detecting and measuring RF energy would be beneficial for at least the reason of improving RF direction finding capabilities.

### BRIEF DESCRIPTION OF THE DRAWINGS

To easily identify the discussion of any particular element or act, the most significant digit or digits in a reference number refer to the figure number in which that element is first introduced.

FIG. 1 illustrates a system diagram of a quantum radio direction finding system.

FIG. 2 illustrates an energy transition diagram of a Rydberg atom used for electromagnetic field sensing.

FIG. 3 illustrates a schematic of a Rydberg atom-based sensor.

FIG. 4 illustrates a 2-D Rydberg atom-based sensor arrangement for direction finding.

FIG. 5A and FIG. 5B illustrate a schematic of a two-beam Rydberg atom-based sensor arrangement.

FIG. 6 illustrates a packaging configuration for a 2-D Rydberg sensor arrangement.

FIG. 7 illustrates an example of airborne integration for a quantum radio direction finding system.

FIG. 8 illustrates a flow diagram for direction finding using a 2-D quantum direction finder to determine an angle of arrival of an electromagnetic signal.

### DETAILED DESCRIPTION OF THE DRAWINGS

The described examples relate to quantum radio frequency (RF) direction finding systems that utilize Rydberg atoms in vapor cells to detect and determine the angle of arrival of RF electromagnetic signals.

The quantum radio frequency direction finding system can comprise three cooperating or integrated subsystems. The sensing unit contains an array of quantum sensor elements based on Rydberg atoms arranged in a two-dimensional geometry. Each sensor element includes or consists of a vapor cell approximately 1 cubic centimeter in size containing alkali metal atoms, with integrated RF electrodes and micro-optic assemblies. The sensors can be arranged with specific spacing specified or optimized for a target frequency range.

A laser and optical system provides precise control of laser excitation to the quantum sensors. Seed lasers and optical amplifiers can generate the desired wavelengths, while an optical system routes the laser light to each sensor element, e.g., through one or more optical fibers. The system includes excitation componentry to optically excite the Rydberg states of the Rydberg atoms in the vapor cells and photodetector circuitry to measure the resulting optical emission.

The electronic control and processing system can use an FPGA and RF System-on-Chip architecture. Digital-to-analog converters can provide control signals (e.g., for the lasers and sensor elements), while analog-to-digital converters can digitize the sensor outputs. Advanced signal processing algorithms can be employed by a signal processor or like circuitry to analyze the phase relationships between sensors to determine angle of arrival.

When an RF signal is present, the Rydberg atoms in each sensor cell detect the field through quantum state interactions. The laser excitation causes electromagnetically induced transparency (EIT), which is modulated by the RF electromagnetic field. The photodetectors measure this modulated optical emission, converting it to electronic signals for signal processing.

The quantum sensing approach provides several advantages over other non-quantum direction finding systems. The quantum sensors exhibit minimal mutual coupling compared to other non-quantum antenna arrays, allowing for closer spacing without degrading performance. The system can operate across a frequency range of 100 kHz to 3 GHz with frequency switching times under 10 microseconds.

For airborne applications, the complete system can occupy approximately 3 cubic feet total volume, with the sensor head occupying 0.5 cubic feet, the laser system occupying 0.8 cubic feet, and the electronics occupying 1 cubic foot. The array configuration can support detection of RF signals with angle of arrival resolution of less than 5 degrees RMS within the 2-20 MHz frequency range.

The system can provide full 360-degree azimuthal coverage with ±45 degrees elevation range. For a compact 8 inch×8 inch array configuration, the system can achieve at least 1.6°RMS angular resolution. A larger 20 inch×20 inch array configuration can provide enhanced resolution of at least 0.7° RMS. The spacing between sensors affects the achievable angular resolution at different frequencies, with examples of spacings ranging from λ/15 to λ/150 of the target RF wavelength.

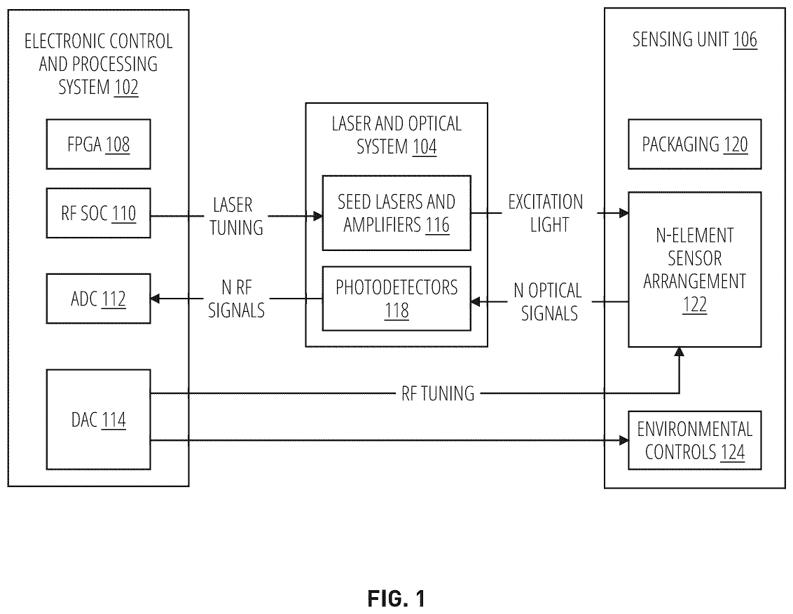

FIG. 1 illustrates an example of portions of a quantum radio frequency (RF) electromagnetic (EM) direction finding system. The system includes an electronic control and processing system 102, a laser and optical system 104, and a sensing unit 106. The excitation light from the laser and optical system 104 optically excites quantum sensor elements in the sensing unit 106, which generate electromagnetically induced transparency (EIT) fluorescence signals that are modulated by RF EM signals arriving from various directions. The photodetectors 118 detect these optical emissions and convert them to corresponding electrical signals. The electronic control and processing system 102 processes these electrical signals to determine phase differences between signals from different sensors, which are used to calculate the angle of arrival of incoming RF EM signals modulating the EIT fluorescence signals.

The electronic control and processing system 102 includes a field-programmable gate array (FPGA) 108, an RF system-on-chip (SoC) 110, an analog-to-digital converter (ADC) 112, and a digital-to-analog converter (DAC) 114. The electronic control and processing system 102 sends electrical signals that control aspects of the laser and optical system 104 (e.g., output wavelength, output optical power, etc.), receives electrical signals from the laser and optical system 104, and processes the received electrical signals into an angle-of-arrival measurement for a detected RF EM signal. The electronic control and processing system 102 can employ one or more signal processing algorithms (e.g., MUSIC) to analyze phase relationships between signals from respective sensors in the sensor arrangement to determine the angle of arrival of incoming RF EM signals.

The FPGA 108 and RF SoC 110 process electrical signals and perform control operations for the quantum RF EM direction finding system. The ADC 112 receives electrical signals output from respective photodetectors 118 and converts them to digital format for processing. The electrical signals can include an indication of a detected RF EM signal in any desired or specified RF band. The DAC 114 generates electrical tuning signals (e.g., for a local oscillator in the N-element sensor arrangement 122) and environmental control signals (e.g., for one or more heaters or thermometers in the sensing unit packaging 120, etc.)

The laser and optical system 104 includes seed lasers and amplifiers 116 that generate excitation light to optically excite the quantum sensor elements. The seed lasers and amplifiers 116 can include any suitable laser systems, and can include any suitable optical components to deliver the excitation light to an N-element sensor arrangement 122. For example, seed lasers and amplifiers 116 can have N outputs (e.g., fiber coupled) that respectively send a corresponding optical signal to respective sensors in the N-element sensor arrangement 122. In another example, seed lasers and amplifiers 116 can have a single optical signal output that is delivered to the packaging 120. In this example, the packaging 120 can include refractive, diffractive, waveguide, or other optical or optoelectronic elements that are configured to send the optical signals from the seed lasers and amplifiers 116 to respective sensors in the N-element sensor arrangement 122.

The laser and optical system 104 additionally includes photodetectors 118 that detect respective optical emissions from respective quantum sensors and convert the detected optical emissions to corresponding electrical signals. The photodetectors 118 can be any suitable detector of optical energy, such as a photodiode, avalanche photodiode, etc., and can include any suitable optical components to receive optical emission from the N-element sensor arrangement 122. For example, photodetectors 118 can comprise N individual photodiode components with associated photodiode circuitry. In another example, photodetectors 118 can comprise a focal plane array (FPA) or other distributed photodetection component (e.g., a pixelated detector) with integrated detection circuitry that can generate respective electrical signals for respective pixels corresponding to respective sensors in the N-element sensor arrangement 122.

Any suitable additional optical elements, such as fiber optic patch cables, coupling lenses (e.g., in-coupling from the laser system to a patch cable, out-coupling at the N-element sensor arrangement 122), mounting hardware, etc., can be included in laser and optical system 104.

The sensing unit 106 comprises packaging 120, which houses an N-element sensor arrangement 122. The sensor elements may be Rydberg atom-based sensors configured in a two-dimensional array geometry. Environmental controls 124 maintain stable operating conditions, such as appropriate temperature for operation of the Rydberg atom-based sensors. Additional details on the sensors and 2D sensor arrangements are given below.

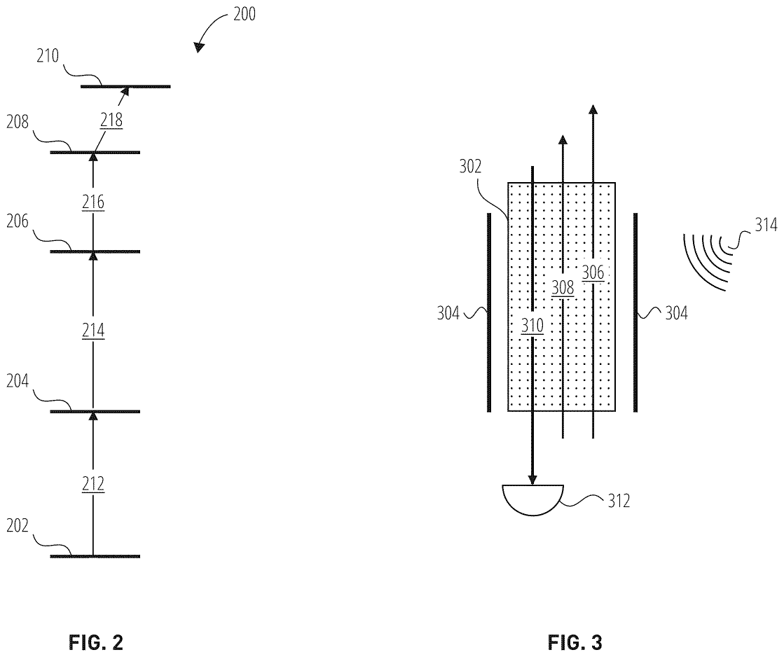

FIG. 2 illustrates an energy level diagram 200 showing quantum state transitions for Rydberg atom-based RF sensing. The energy level diagram 200 shows quantum energy states and transitions in the absence of any external electric or magnetic fields, including a first state 202, second state 204, third state 206, first Rydberg state 208, and second Rydberg state 210, that can correspond to any suitable energy levels in atomic particles such as rubidium, cesium, etc. Selection of particular energy levels can determine a particular RF band for sensing, along with the appropriate selection of optical frequencies needed to excite the relevant transitions, as described below. Additionally, external electric and magnetic fields can provide tuning parameters for the quantum energy states, e.g., through the DC Stark effect (energy shift in a DC electric field), AC Stark shift (energy shift in a time-varying electric field), and Zeeman effect (energy shift in a magnetic field).

The first state 202 corresponds to a ground state of a quantum particle (e.g., 6S1/2 energy level of rubidium). The second state 204 represents an intermediate excited state (e.g., 6P3/2 energy level of rubidium) accessed through optical excitation with a probe laser (e.g., at 852 nm). The third state 206 corresponds to another intermediate state (e.g., 6D5/2 energy level) reached through optical excitation with a coupling laser (e.g., at 1140 nm).

The first Rydberg state 208 and second Rydberg state 210 represent highly excited quantum states with high principal quantum numbers. The RF energy 218 couples these Rydberg states, enabling RF field detection through electromagnetically induced transparency, such as discussed further with respect to FIG. 3.

The states are connected by transition energies, including first transition energy 212, second transition energy 214, third transition energy 216, and RF energy 218. The transitions between states are driven by laser fields and RF fields. A probe laser induces the first transition energy 212 between states 202 and 204. A coupling laser provides the second transition energy 214 to excite atoms to third state 206. The third transition energy 216 promotes atoms to the Rydberg states.

The RF energy 218 couples the Rydberg states, with the transition frequency matching the RF field frequency to be detected. This allows sensing RF fields within particular frequency sub-bands in a frequency band ranging from 100 kHz to 3 GHz, by selecting appropriate Rydberg states through laser frequency tuning and, in some examples, by applying external electric fields to extend the range of available transition frequencies for RF energy 218.

The energy level diagram 200 enables phase-sensitive RF field detection through optical excitation and readout. The probe laser transmission is modified by the RF field coupling of Rydberg states, providing a mechanism for measuring both amplitude and phase of RF signals.

FIG. 3 illustrates a schematic of a single Rydberg atom-based sensor that can be used for detecting RF EM signals. The Rydberg sensor 300 comprises a quantum particles 302 in a vapor cell, a field plates 304, a pump beam 306, a coupling beam 308, a probe beam 310, a photodiode 312, and an RF EM signal 314.

The quantum particles 302 can be any suitable atomic species, such as an alkali metal atoms (e.g., rubidium or cesium) in gaseous form. The quantum particles 302 can be held in a vapor cell comprising a sealed glass container with optical windows that allow laser beams to pass through. Additionally, the vapor cell can be heated (e.g., 60° C.) such as to maintain an appropriate atomic vapor density.

The field plates 304 can be used to provide an external electric field or magnetic field. As described above with respect to FIG. 2, an external RF EM signal can be detected when the RF EM transition frequency matches the energy transition between specified or selected Rydberg states. The field plates 304 can provide a DC field or an AC field to shift the transition energies and thereby extend a range of detectable RF EM signals.

There are three laser beams shown in FIG. 3, although other laser arrangements can be used for generating an EIT signal, where the laser wavelengths are selected to match the transition frequencies of a selected energy level diagram 200:
A probe beam 310 (typically near 780 nm or 850 nm) that drives the ground state to first excited state transition. The frequency of the probe beam 310 can be scanned on-resonance and off-resonance to generate an EIT fluorescence signal in the quantum particles 302.
A pump beam 306 and coupling beam 308 that, when photons from both are absorbed, excite quantum particles 302 to the Rydberg state.

The lasers can be frequency-stabilized and tunable, with controllable output power. As shown in FIG. 3, the laser beams can be arranged in a counter-propagating configuration through the vapor cell. By using a counter-propagating configuration, the laser beams overlap within the vapor cell such that a given proportion of the atomic vapor can absorb photons from each of the pump beam 306, coupling beam 308, and probe beam 310. When configured, the coupling beam 308 creates a quantum interference effect that makes the quantum particles 302 transparent to the probe beam 310, which can be referred to as electromagnetically induced transparency (EIT). The EIT signal appears as a narrow peak in probe transmission when both lasers are on resonance.

The width and height of this transparency window provide information about the coherence of the atomic system.

Additional optical components not shown in FIG. 3 that can be used include:
Beamsplitters and mirrors to direct and combine laser beams,
Lenses for beam collimation and focusing, and
Polarization control elements.

These additional optical components can be table-top optical assemblies (e.g., laboratory scale), micro-optic assemblies, or photonic components.

FIG. 3 also includes a photodiode 312 that measures an intensity of transmitted probe light (e.g., as a frequency of the probe beam 310 is scanned through the ground state transition energy). The electrical signal from the photodiode 312 can comprise the EIT spectral features that are processed into an electrical representation of a detected RF EM signal 314.

Electric Field Measurement: When the Rydberg sensor 300 is configured to sense an RF EM signal 314, the RF EM signal 314 can couple to transitions between Rydberg states. This coupling manifests in two possible ways:
a) Autler-Townes Splitting, where for resonant fields, the EIT peak splits into two peaks that is proportional to the electric field amplitude of the RF EM signal 314. The field strength of RF EM signal 314 can be calculated using the formula: E=(h×Δf)/μwhere h is Planck's constant, Δf is the measured frequency splitting, and μ is the transition dipole moment for the Rydberg atom.
b) AC Stark Shift, where, for off-resonant fields, the EIT peak shifts in frequency, and the amount of frequency shift is proportional to the square of the electric field strength.

The transmission of the probe beam 310 is therefore used to indicate the presence of the RF EM signal 314, and lock-in detection techniques can be employed by modulating either the coupling laser or the RF field.

A measurement of the peak splitting (Autler Townes) or the frequency shift (AC Stark Shift) can be converted to electric field strength using the appropriate calibration factors. The Rydberg sensor 300 can be operated in different modes, such as a continuous monitoring, a spectrum analysis, and a vector detection mode. In continuous monitoring, the EIT peak position or splitting is recorded and tracked in real-time. In spectrum analysis, the excitation scheme can be scanned infrequency to characterize frequency-dependent responses. Additionally, multiple laser beam configurations (e.g., counter-propagating at multiple angles) can be used to determine field direction.

The Rydberg sensor 300 utilizes the extreme sensitivity of Rydberg states to electric fields, combined with the precision of laser spectroscopy. The measurement of an RF EM signal 314 is based on fundamental atomic properties, making it self-calibrated and traceable to SI units. The technique can provide high sensitivity measurements over a wide frequency range from MHz to THz, with minimal perturbation of the field being measured.

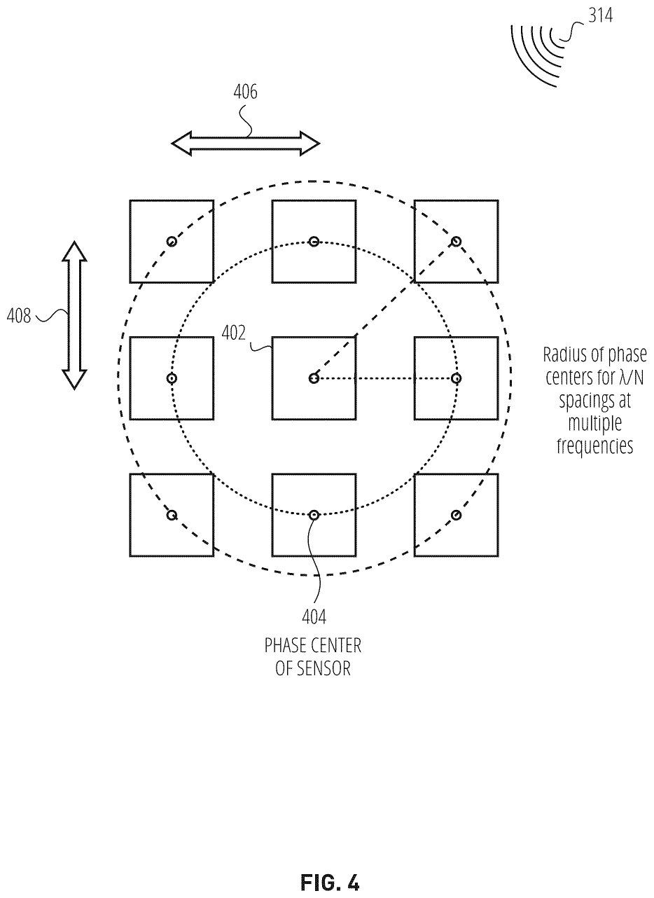

FIG. 4 illustrates a 2-D Rydberg atom-based sensor arrangement for direction finding. The 2D sensor arrangement 400 comprises multiple Rydberg sensors 402 having respective phase centers 404, a first direction separation 406, and a second direction separation 408. The 2D sensor arrangement 400 combines quantum sensing technology with phase interferometry techniques to determine the angle of arrival of RF EM signals.

The multiple Rydberg sensors 402 used in the 2D sensor arrangement 400 can be Rydberg sensors (e.g., such as Rydberg sensor 300) that use the same energy level diagram 200 for RF EM sensing. For example, Rydberg sensors 402 can include vapor cells approximately 1 cubic centimeter in size that contain integrated RF electrodes and micro-optic assemblies. In some examples, one or more of Rydberg sensors 402 can be a Rydberg sensor 300 of one type (e.g., rubidium, using a first set of energy transitions in rubidium, etc.), while a distinct subset of Rydberg sensors 402 can be a Rydberg sensor 300 of a second type (e.g., cesium, using a second set of energy transitions in rubidium, etc.).

As shown in FIG. 4, the multiple Rydberg sensors 402 can be arranged in a two-dimensional geometry. The two-dimensional geometry can have a first direction separation 406 and a second direction separation 408 between respective sensors. These separations may be configured for a desired angular resolution in a respective frequency range. The spacing between sensors can range from λ/15 to λ/150, where λ is the wavelength of the target RF frequency. The 2D sensor arrangement 400 shown in FIG. 4 can detect RF EM signals across a frequency range of 100 kHz to 3 GHz. For a compact 8″×8″ arrangement, the system achieves 1.6° RMS angular resolution. A larger 20″×20″ array configuration provides enhanced resolution of 0.7° RMS.

Phase centers 404 can be positioned at specific locations within each sensor element 402. The phase centers 404 enable measurement of phase differences between sensor elements to determine angle of arrival of incoming RF signals, and affects the achievable angular resolution at different frequencies. The dotted and dashed lines connecting the phase centers indicate the phase relationships used for interferometric measurements. The array geometry enables measurement of both azimuth and elevation angles of incoming RF signals.

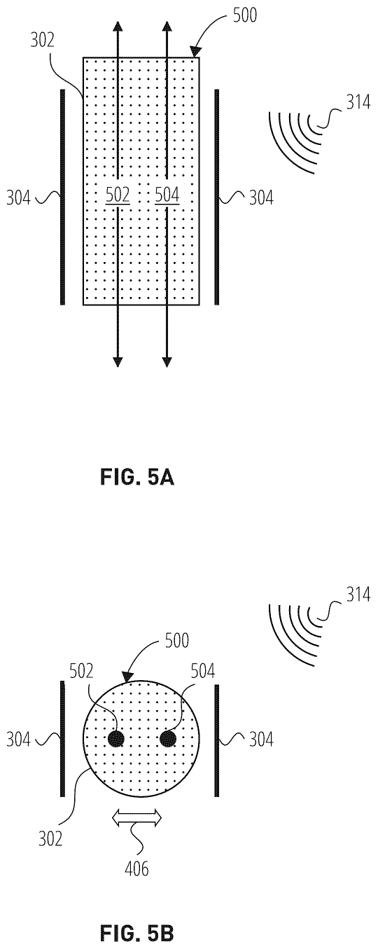

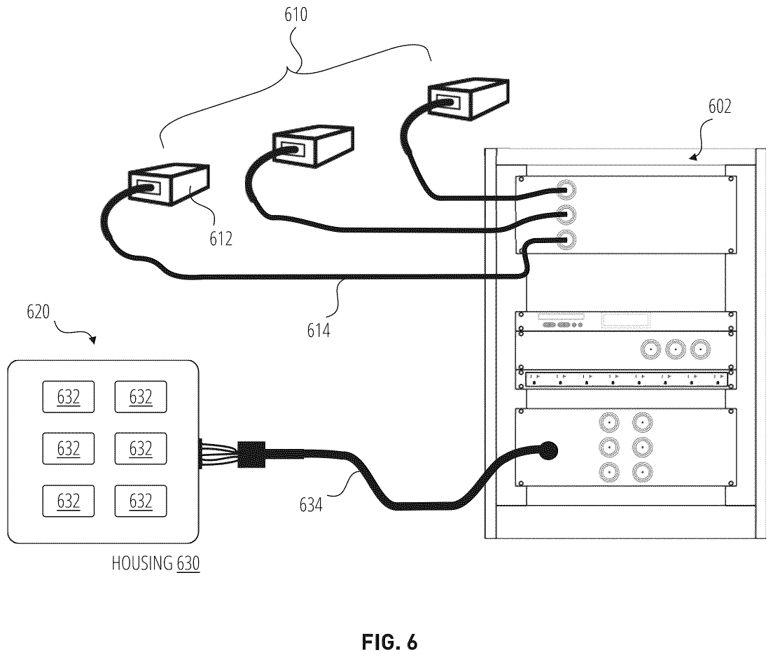

The quantum sensor elements 402 exhibit minimal mutual coupling compared to traditional antenna arrays. This allows for closer spacing between respective sensors. The array may be configured in either a single housing or multiple housings, as described below in FIG. 5A through FIG. 6.

FIG. 5A and FIG. 5B illustrate a schematic of a two-beam Rydberg atom-based sensor arrangement. A quantum sensor element 500 (e.g., Rydberg sensor 300) comprising quantum particles 302 can be configured with a first probe beam 502 and a second probe beam 504. Additional optical beams (e.g., pump beam 306, coupling beam 308) can be configured to be counter-propagating to first probe beam 502 and second probe beam 504, although not shown in FIGS. 5A and 5B.

The first probe beam 502 and second probe beam 504 generate electromagnetically induced transparency signals that are modulated by the incoming RF electromagnetic signal 314, as described above in FIG. 3. The first probe beam 502 and second probe beam 504 connect to photodetector circuitry that measures the optical emission and outputs an electrical signal. The electrical signals are processed to determine phase differences between sensor elements in an array configuration. The phase differences enable calculation of the angle of arrival of incoming RF electromagnetic signals. In the two-beam configuration of FIGS. 5A and 5B, each probe beam can act as a distinct sensor, generating a two-element array for direction finding that uses a single vapor cell.

The spacing 406 between probe beams affects the achievable angular resolution, with typical spacings ranging from λ/ 15 to λ/ 150 (e.g., 10 mm), where λ is the target RF wavelength. The probe beams may be fiber-coupled to allow flexible positioning and alignment.

FIG. 6 illustrates example packaging configurations for a 2-D Rydberg sensor arrangement. In the example of FIG. 6, a rack 602 can be configured with necessary electronic and optical components (e.g., for electronic control and processing system 102, laser and optical system 104).

A first packaging configuration 610 can include an arrangement of Rydberg sensors (e.g., Rydberg sensor 300) where a given sensor enclosure 612 is connected to the electronic and optical components on rack 602 through a given umbilical cord or, e.g., cabling 614, or similar arrangement. Each sensor enclosure 612 can house the optical, electronic, and physical components (e.g., vapor cell) for a complete RF EM Rydberg sensor. That is, in first packaging configuration 610, sensor enclosures 612 can be operated independently and positioned through any suitable mechanical fixtures. The positioning of the sensor enclosures 612 can determine the 2-D sensor arrangement for direction finding performance at a given frequency, etc. In some examples, the first packaging configuration 610 can be configured (e.g., in a 20″×20″ array) to have approximately 0.7° RMS resolution.

A second packaging configuration 620 can include an arrangement of packaged vapor cells 632 inside a single housing 630, with suitable micro-optic assemblies for respective vapor cells. A given packaged vapor cell 632 is addressed by the electronic and optical components on rack 602 through a larger cabling 614 comprising optical cabling (e.g., fiber patch cables) and electrical cabling having enough channels (e.g., optical channels, electrical channels) to send and receive optical and electronic signals to all sensing units (e.g. packaged vapor cells 632) in the second packaging configuration 620. In some examples, a dual-beam vapor cell arrangement, as shown in FIG. 5A and FIG. 5B, can be housed in the second packaging configuration 620. The second packaging configuration 620 integrates respective vapor cells into an enclosure and the vapor cell locations can be positioned in a permanent (or semi-permanent) arrangement for direction finding operation in a compact package. In some examples, the second packaging configuration 620 can be compact, such as an 8″×8″ array, and can have a direction finding capability of approximately 1.6 ° RMS resolution.

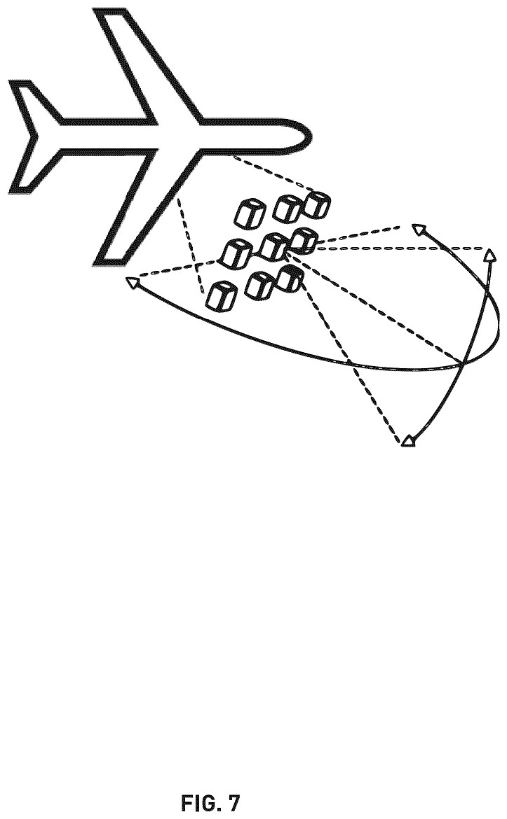

FIG. 7 illustrates an example of airborne integration for a quantum radio direction finding system. FIG. 7 includes an aircraft with an array of quantum sensor elements (e.g., mounted underneath). The sensor array provides direction finding capabilities for detecting RF electromagnetic signals as described above while the platform is in flight.

The quantum sensor elements are arranged in a two-dimensional geometry to enable measurement of azimuth angles up to 360 degrees. The array provides coverage from horizon to −45 degrees elevation angle relative to the wing level of the aircraft. The quantum sensor elements provide a measurement system that is decoupled from the desired sensing frequency, unlike antenna systems. Additionally, the quantum sensor elements operate outside the Chu limit.

The sensor array integrates with laser and optical systems that provide excitation light to the quantum sensor elements. The sensors connect to electronic control and processing systems through optical fibers and RF cabling.

The system operates across a frequency range of 100 kHz to 3 GHz with frequency switching times under 10 microseconds. The array achieves angle of arrival resolution of less than 5 degrees RMS within the 2-20 MHz frequency range.

The quantum sensor elements exhibit minimal mutual coupling compared to traditional antenna arrays. This allows for closer spacing between elements without degrading performance. The array may be configured in either a single housing or multiple housings depending on the airborne platform requirements, as described above in FIG. 6.

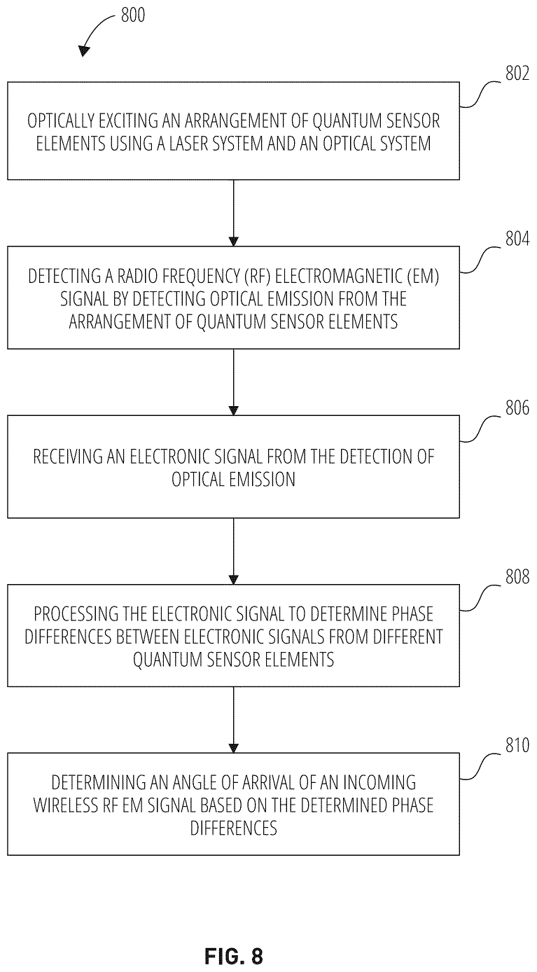

FIG. 8 illustrates an example of a method 800 for quantum radio direction finding. Although the example routine depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

In some examples, the method includes optically exciting an arrangement of quantum sensor elements using a laser system and an optical system at block 802.

In some examples, the method includes detecting a radio frequency (RF) electromagnetic (EM) signal by detecting optical emission from the arrangement of quantum sensor elements at block 804.

In some examples, the method includes receiving an electrical signal from the detection of optical emission at block 806.

In some examples, the method includes processing the electronic signal to determine phase differences between electronic signals from different quantum sensor elements at block 808.

In some examples, the method includes determining an angle of arrival of an incoming wireless RF EM signal based on the determined phase differences at block 810.

Example 1 is a quantum radio frequency (RF) electromagnetic (EM) signal direction finding system, comprising: an arrangement of quantum sensor elements, wherein respective quantum sensor elements are configured to detect an RF EM signal; a laser system and an optical system comprising: excitation componentry arranged to optically excite the quantum sensor elements; and photodetector circuitry to detect optical emission from respective ones of the quantum sensor elements; an electronic control and processing circuit configured to: receive electronic signals from the photodetector circuitry; process the electronic signals to determine phase differences between electronic signals from respective quantum sensor elements; and determine an angle of arrival of an incoming wireless RF EM signal based on the determined phase differences.

In Example 2, the subject matter of Example 1 includes, wherein the quantum RF EM signal direction finding system is configured to detect a wireless RF EM signal within a frequency range of 100 kHz to 3 GHz.

In Example 3, the subject matter of Example 2 includes, including band selection componentry that is configured to switch among different frequency bands within the range of 100 kHz to 3 GHz to detect the incoming wireless RF EM signal.

In Example 4, the subject matter of Examples 1-3 includes, wherein at least one of the quantum sensor elements comprises a Rydberg atom-based sensor.

In Example 5, the subject matter of Example 4 includes, wherein at least one quantum sensor is configured to provide optical emission including an electromagnetically induced transparency (EIT) fluorescence signal.

In Example 6, the subject matter of Example 5 includes, wherein the at least one quantum sensor element is configured to produce the EIT fluorescence signal in response to the incoming wireless RF EM signal.

In Example 7, the subject matter of Examples 1-6 includes, wherein the arrangement of quantum sensor elements is configured to provide an interferometer to perform phase interferometry for direction finding.

In Example 8, the subject matter of Examples 1-7 includes, wherein the electronic control and processing circuit is further configured to determine a speed of a target object that produces the incoming wireless RF EM signal.

In Example 9, the subject matter of Examples 1-8 includes, wherein the arrangement of quantum sensor elements has less mutual coupling between individual ones of the arrangement of quantum sensor elements compared to individual ones of the arrangement of antenna elements in a like arrangement of antenna elements.

In Example 10, the subject matter of Examples 1-9 includes, wherein the arrangement of quantum sensor elements is configured in a two-dimensional geometry, and wherein the electronic control and processing system is configured to measure an azimuth angle of a target object that produces the incoming wireless RF EM signal.

In Example 11, the subject matter of Examples 1-10 includes, wherein the arrangement of quantum sensor elements is packaged in a single housing.

In Example 12, the subject matter of Example 11 includes, wherein respective quantum sensor elements within the single housing are optically excited by a shared laser input to the single housing.

In Example 13, the subject matter of Examples 1-12 includes, wherein the arrangement of quantum sensor elements is packaged to comprise multiple housings.

In Example 14, the subject matter of Example 13 includes, wherein respective housings are optically linked.

In Example 15, the subject matter of Examples 1-14 includes, wherein the system is included in an airborne platform.

Example 16 is a method for quantum radio direction finding, comprising: optically exciting an arrangement of quantum sensor elements using a laser system and an optical system; detecting a radio frequency (RF) electromagnetic (EM) signal using photodetector circuitry configured to detect optical emission from respective ones of the arrangement of quantum sensor elements; receiving an electronic signal from the photodetector circuitry; processing the electronic signal to determine phase differences between electronic signals from different quantum sensor elements; and determining an angle of arrival of an incoming wireless RF EM signal based on the determined phase differences.

In Example 17, the subject matter of Example 16 includes, wherein the incoming RF EM signal is in a frequency range of 100 kHz to 3 GHz.

In Example 18, the subject matter of Example 17 includes, further comprising using band selection componentry that is configured to switch among different frequency bands within the range of 100 kHz to 3 GHz to detect the incoming wireless RF EM signal.

In Example 19, the subject matter of Examples 16-18 includes, wherein at least one of the quantum sensor elements comprises a Rydberg atom-based sensor.

Example 20 is at least one machine-readable medium including instructions that, when executed by processing circuitry, cause the processing circuitry to perform operations to implement of any of Examples 1-19.

Example 21 is an apparatus comprising means to implement of any of Examples 1-19.

Example 22 is a system to implement of any of Examples 1-19.

Example 23 is a method to implement of any of Examples 1-19.

Other technical features and example embodiments may be readily apparent to one skilled in the art from the figures, descriptions, and claims herein.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated. These details are provided for the purpose of example and the invention may be practiced according to the claims without some or all of these specific details. For the purpose of clarity, technical material that is known in the technical fields related to the invention has not been described in detail so that the invention is not unnecessarily obscured.

It will also be understood that, although the terms first, second, etc. are, in some instances, used herein to describe various elements, these elements should not be limited by these terms. These terms are used only to distinguish one element from another. For example, a first beam could be termed a second beam, and, similarly, a second beam could be termed a first beam, without departing from the scope of the various described embodiments. The first beam and the second beam are both beams, but they are not the same beam.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

What is claimed is:

1. A quantum radio frequency (RF) electromagnetic (EM) signal direction finding system, comprising:
an arrangement of quantum sensor elements, wherein respective quantum sensor elements are configured to detect an RF EM signal;
a laser system and an optical system comprising:
excitation componentry arranged to optically excite the quantum sensor elements; and
photodetector circuitry to detect optical emission from respective ones of the quantum sensor elements; and
an electronic control and processing circuit configured to:
receive electronic signals from the photodetector circuitry;
process the electronic signals to determine phase differences between electronic signals from respective quantum sensor elements; and
determine an angle of arrival of an incoming wireless RF EM signal based on the determined phase differences.

2. The system of claim 1, wherein the quantum RF EM signal direction finding system is configured to detect a wireless RF EM signal within a frequency range of 100 kHz to 3 GHz.

3. The system of claim 2, including band selection componentry that is configured to switch among different frequency bands within the range of 100 kHz to 3 GHz to detect the incoming wireless RF EM signal.

4. The system of claim 1, wherein at least one of the quantum sensor elements comprises a Rydberg atom-based sensor.

5. The system of claim 4, wherein at least one quantum sensor is configured to provide optical emission including an electromagnetically induced transparency (EIT) fluorescence signal.

6. The system of claim 5, wherein the at least one quantum sensor element is configured to produce the EIT fluorescence signal in response to the incoming wireless RF EM signal.

7. The system of claim 1, wherein the arrangement of quantum sensor elements is configured to provide an interferometer to perform phase interferometry for direction finding.

8. The system of claim 1, wherein the electronic control and processing circuit is further configured to determine a speed of a target object that produces the incoming wireless RF EM signal.

9. The system of claim 1, wherein the arrangement of quantum sensor elements has less mutual coupling between individual ones of the arrangement of quantum sensor elements compared to individual ones of the arrangement of antenna elements in a like arrangement of antenna elements.

10. The system of claim 1, wherein the arrangement of quantum sensor elements is configured in a two-dimensional geometry, and wherein the electronic control and processing system is configured to measure an azimuth angle of a target object that produces the incoming wireless RF EM signal.

11. The system of claim 1, wherein the arrangement of quantum sensor elements is packaged in a single housing.

12. The system of claim 11, wherein respective quantum sensor elements within the single housing are optically excited by a shared laser input to the single housing.

13. The system of claim 1, wherein the arrangement of quantum sensor elements is packaged to comprise multiple housings.

14. The system of claim 13, wherein respective housings are optically linked.

15. The system of claim 1, wherein the system is included in an airborne platform.

16. A method for quantum radio direction finding, comprising:
optically exciting an arrangement of quantum sensor elements using a laser system and an optical system;
detecting a radio frequency (RF) electromagnetic (EM) signal using photodetector circuitry configured to detect optical emission from respective ones of the arrangement of quantum sensor elements;
receiving an electronic signal from the photodetector circuitry;
processing the electronic signal to determine phase differences between electronic signals from different quantum sensor elements; and
determining an angle of arrival of an incoming wireless RF EM signal based on the determined phase differences.

17. The method of claim 16, wherein the incoming RF EM signal is in a frequency range of 100 kHz to 3 GHz.

18. The method of claim 17, further comprising using band selection componentry that is configured to switch among different frequency bands within the range of 100 kHz to 3 GHz to detect the incoming wireless RF EM signal.

19. The method of claim 16, wherein at least one of the quantum sensor elements comprises a Rydberg atom-based sensor.

20. A quantum radio frequency (RF) electromagnetic (EM) signal direction finding system, comprising:
an arrangement of quantum sensor elements configured in a two-dimensional geometry, wherein respective quantum sensor elements are configured to detect an incoming wireless RF EM signal, wherein at least one of the quantum sensor elements comprises a Rydberg atom-based sensor that is configured to provide optical emission including an electromagnetically induced transparency (EIT) fluorescence signal in response to the incoming wireless RF EM signal;
a laser system and an optical system comprising:
excitation componentry arranged to optically excite the quantum sensor elements; and
photodetector circuitry to detect optical emission from respective ones of the quantum sensor elements; and
an electronic control and processing circuit configured to:
receive electronic signals from the photodetector circuitry;
process the electronic signals to determine phase differences between electronic signals from respective quantum sensor elements;
determine an angle of arrival of an incoming wireless RF EM signal based on the determined phase differences; and
determine an azimuth angle and a speed of a target object that produces the incoming wireless RF EM signal.
